(19) United States
(12) Patent Application Publication
(10) Pub. No.: US 2008/0169509 A1
(43) Pub. Date: Jul. 17, 2008

(54) Semiconductor device

(75) Inventor: Masanori Tanaka, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/007,759

(22) Filed: Jan. 15, 2008

(30) Foreign Application Priority Data
Jan. 16, 2007 (JP) 2007-007453

(51) Int. Cl. H01L 27/088

(52) U.S. Cl. 257/360; 257/E27.06

(57) ABSTRACT

A semiconductor device includes a first well of a first conductive type formed in a surface portion of a semiconductor substrate; a first contact group connected with the first well; a second well of a second conductive type formed to surround the first well in the surface portion of the semiconductor substrate; a first guard ring provided on the second well; a second contact group connected with the first guard ring; a third well of the first conductive type formed to surround the second well in the surface portion of the semiconductor substrate; a second guard ring provided on the third well; and a third contact group connected with the second guard ring. The first to third wells form a transistor, and a current flowing through the transistor is suppressed.

### BACKGROUND OF THE INVENTION

1. Field of the Invention

The present invention relates to a semiconductor device, and more particularly relates to a semiconductor device that contains a guard ring for preventing latch-up of an electrostatic discharge protection circuit. This patent application is based on Japanese Patent Application No. 2007-007453. The disclosure of the Japanese Patent Application is incorporated herein by reference.

2. Description of Related Art

A guard ring is known as a technique for blocking off a noise to a circuit including a MOS (Metal Oxide Semiconductor) transistor. Typically, in order to absorb carriers in a well in which the MOS transistor is formed, a diffusion layer of a same conductive type as the well and a large number of contacts are provided in the guard ring. Also, there is known a technique in which a plurality of guard rings are arranged around a circuit so that the blocking-off performance against the noise is improved. Conventional techniques are described in Japanese Laid Open Patent Application (JP-A-Heisei, 5-110002) (refer to a first conventional example) and Japanese Laid Open Patent Application (JP-P2001-148466A) (refer to a second conventional example).

On the other hand, an electrostatic discharge (ESD) protection circuit for preventing an internal circuit from electrostatic discharge (ESD) is provided between a pad and the internal circuit in a semiconductor integrated circuit. At this time, in order to prevent the latch-up of the ESD protection circuit due to noise, the guard ring is arranged around an ESD protection element.

FIG. 8 is a plan view showing a layout of an ESD protection element 60 and the guard rings in a conventional technique. With reference to FIG. 8, an ESD protection element 60 is provided with a plurality of P-type MOS transistors formed on an N-well 61. Also, the N-well 61 serving as the substrate of the ESD protection element 60 is electrically connected through an N⁺ diffusion layer 62 and a contact 63 to Pads. A P-type guard ring 40 is arranged to surround the periphery of the N-well 61. Moreover, an N-type guard ring 50 is arranged to surround its periphery.

The P-type guard ring 40 is provided with a P-well 41 adjacent to the N-well 61, and this is connected through a P⁺-type diffusion layer 42 and contacts 43 to a ground potential GND. The N-type guard ring 50 is provided with an N-well 51 adjacent to the P-well 41, and this is connected through an N-type diffusion layer 52 and contacts 53 to a power source voltage VDD. Here, the P-type guard ring 40 and the N-type guard ring 50 are provided with a large number of contacts 43 and 53, in order to absorb as many carriers as possible.

In the semiconductor device shown in FIG. 8, a parasitic bipolar element is formed in which the N-well 51 serves as a collector, the P-well 41 serves as a base, and the N-well 61 serves as an emitter. For this reason, when a negative over-voltage with respect to the power source VDD is applied to the Pad through the ESD protection element, a very large current flow into this parasitic bipolar element, and there is a case that the parasitic bipolar element is broken. In detail, when the negative ESD voltage with respect to the power source VDD is applied to the Pad, a portion between the P-well 41 and the N-well 61 is forwardly biased. A parasitic NPN bipolar element operates in accordance with a base current flowing from the P-well 41 to the N-well 61, and the ESD current flows between the N-well 51 and the N-well 61. In particular, when the width of the P-well 41 corresponding to the base is narrow, large collector current flows based on the small base current, and the parasitic NPN bipolar transistor is broken. To this situation, there would be considered a method of making the width of the P-well 41 corresponding to the base wider to decrease the gain of the parasitic bipolar element or a method of making the width of the N-well 51 wider to improve the breakdown resistance. However, these methods cause the increase in a layout area.

### SUMMARY

In a first embodiment of the present invention, a semiconductor device includes a first well of a first conductive type formed in a surface portion of a semiconductor substrate; a first contact group connected with the first well; a second well of a second conductive type formed to surround the first well in the surface portion of the semiconductor substrate; a first guard ring provided on the second well; a second contact group connected with the first guard ring; a third well of the first conductive type formed to surround the second well in the surface portion of the semiconductor substrate; a second guard ring provided on the third well; and a third contact group connected with the second guard ring. The first to third wells form a transistor, and a current flowing through the transistor is suppressed.

In a second embodiment of the present invention, a semiconductor device includes a first well; a pad connected with the first well; a first guard ring provided around the first well; and a second guard ring provided around the first guard ring. The pad is connected with a signal, and the first well is of a first conductive type and connected with the pad through first contacts provided on the first well. The first guard ring comprises a second well of a second conductive type and second contacts provided on the second well to supply a first power source voltage to the second well. The second guard ring comprises a third well of the first conductive type and third contacts provided on the third well to supply a second power source voltage to the third well. The third contacts are provided in a contact region of the second guard ring other than a region thereof which opposes to the first contacts through the first guard ring such that a current flowing through the first to third wells is suppressed.

In a third embodiment of the present invention, a semiconductor device includes a pad for input or output of a signal; a rectangular N-type well provided with an ESD protection element and electrically connected with the pad through a first contact group; a P-type guard ring provided around the N-type well to have a predetermined width and connected with a low power source through a second contact group; and an N-type guard ring provided around the P-type guard ring to have a predetermined width and connected with a high power source through a third contact group. The first contact group is provided in a predetermined interval along a side of the N-type well, the second contact group is provided on the P-type guard ring in a predetermined interval, and the third contact group is provided on an N-type guard ring in a predetermined interval. The third contact group is not provided for a first region of the N-type guard ring opposing to the first contact group through the P-type guard ring and provided for a second region of the N-type guard ring other than the first region.

According to the semiconductor device of the present invention, without any deterioration in the latch-up endurance, it is possible to suppress an operation of a parasitic bipolar element formed due to a guard ring, and it is also possible to prevent the breakdown of the element. Also, it is possible to improve the ESD endurance of an ESD preventing element around which the guard ring is arranged. Moreover, it is possible to reduce the circuit area of a semiconductor device that contains the element around which the guard ring is arranged.

### BRIEF DESCRIPTION OF THE DRAWINGS

The above and other objects, advantages and features of the present invention will be more apparent from the following description of certain embodiments taken in conjunction with the accompanying drawings, in which:

FIG. 1 is a circuit diagram showing a discharging route of an ESD current in a semiconductor device according to the present invention;

FIG. 2 is a circuit diagram showing the discharging route of the ESD current in the semiconductor device in which an ESD protection circuit cannot be installed between a power source VDD and Pad;

FIG. 3 is a plan view showing a layout of an ESD protection circuit having a guard ring according to the present invention;

FIG. 4 is a plan view showing a positional relation in an embodiment between contacts provided on an N-well and the guard ring according to the present invention;

FIG. 5 is a plan view showing an ESD current route with regard to discharging inside a parasitic bipolar element according to the present invention;

FIG. 6 is a sectional view on D-D′ showing the ESD current route inside the parasitic bipolar element according to the present invention;

FIG. 7 is a diagrammatic view showing a section on E-D′ indicating the ESD current route inside the parasitic bipolar element according to the present invention and a positional relation between the contacts; and

FIG. 8 is a plan view showing a layout of an ESD protection circuit containing a guard ring according to a conventional technique.

### DESCRIPTION OF THE PREFERRED EMBODIMENTS

Hereinafter, a semiconductor device according to embodiments of the present invention will be described in detail with reference to the attached drawings. In this embodiments, the semiconductor device will be described which contains an electrostatic discharge (ESD) protection element for preventing ESD breakdown of an internal circuit, and guard rings for improving the latch-up endurance of the ESD protection element.

### [Route of ESD Current]

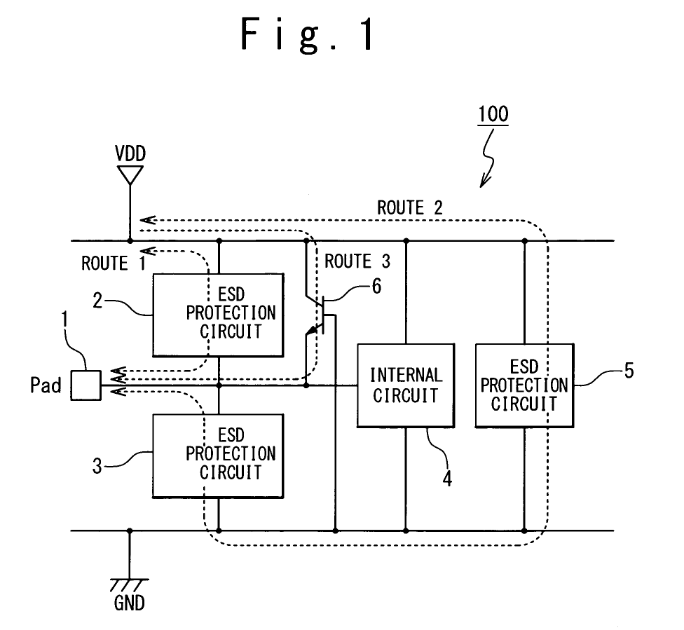

The configuration of a semiconductor device 100 according to the present invention and a discharging route of ESD current in the semiconductor device 100 will be described below with reference to FIGS. 1 to 3. FIG. 1 is a circuit diagram showing the configuration of the semiconductor device 100 is provided with ESD protection circuits 2, 3 and 5 which allow the ESD current to flow in order to protect an internal circuit 4. The internal circuit 4 is arranged between a power source VDD as a first power source and a ground GND as a second power source, and is connected to a Pad 1 for inputting or outputting a signal. The ESD protection circuit 2 is arranged between the power source VDD and the Pad 1, to pass the ESD current between the Pad 1 and the power source VDD. The ESD protection circuit 3 is arranged between the power source GND and the Pad 1, to pass the ESD current between the power source GND and the Pad 1. The ESD protection circuit 5 is arranged between the power source VDD and the power source GND, to pass the ESD current between the power source VDD and the power source GND. Also, as described later, since guard rings are arranged around the ESD protection circuits 2 and 3, a parasitic bipolar element is constituted by using the ESD protection circuits 2 and 3 and the guard ring. FIG. 1 shows a parasitic bipolar element 6 composed of the ESD protection circuit 3 and the guard ring.

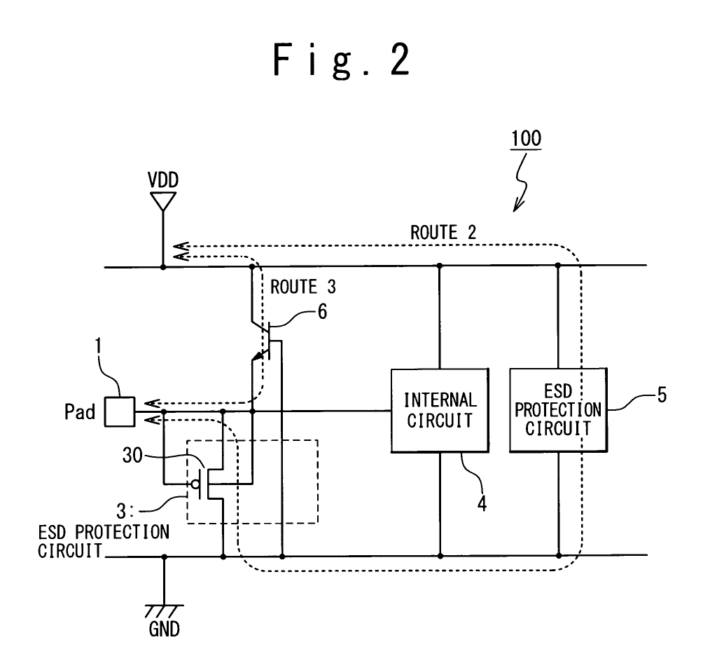

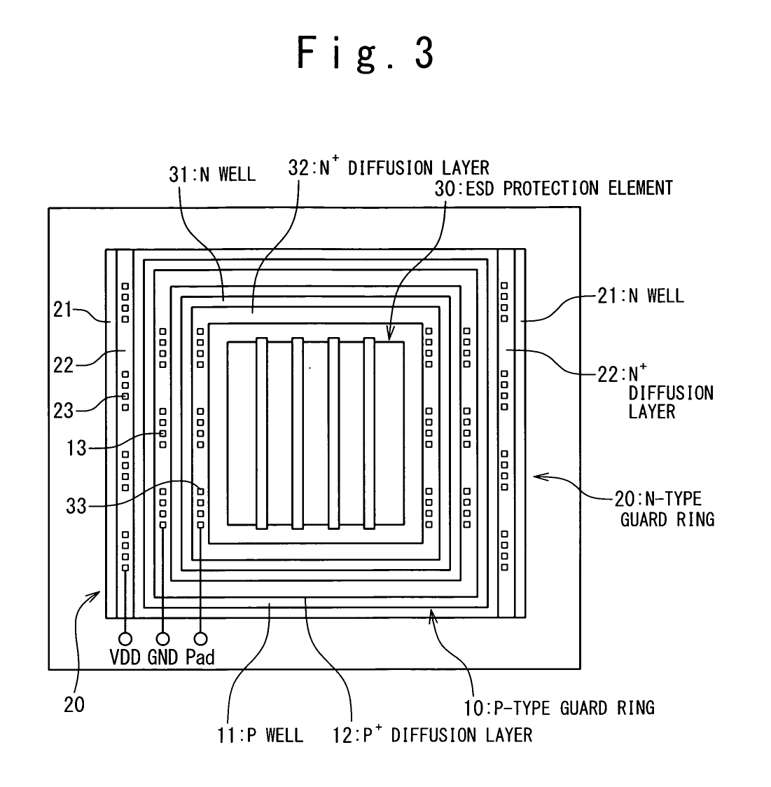

As shown in FIG. 3, the guard rings are arranged around an ESD protection element 30. The ESD protection circuit 3 is provided with a plurality of P-type MOS transistors arranged in an N-well 31 as the ESD protection element 30 and are connected in parallel. In each of the plurality of P-type MOS transistors, as shown in FIG. 2, a drain and a gate are connected to the Pad 1, and a source is connected to the power source GND. Also, an N-well 31 serving as the substrate of the ESD protection circuit 3 is electrically connected through an N⁺-type diffusion layer 32 and contacts 33 to the Pad 1 by wirings (not shown). A P-type guard ring 10 is arranged to surround the periphery of the N-well 31. Moreover, an N-type guard ring 20 is arranged to surround the periphery of the P-type guard ring 10. The P-type guard ring 10 is provided with a P-well 11 adjacent to the N-well 31, and is connected through a P⁺-type diffusion layer 12 and contacts 13 to a power source GND wiring (not shown). The N-type guard ring 20 is provided with an N-well 21 adjacent to the P-well 11, and is connected through an N⁺-type diffusion layer 22 and contacts 23 to a power source VDD wiring (not shown).

With such a configuration, by the N-well 31 in which the ESD protection element 30 is formed, and the P-type guard ring 10 and the N-type guard ring 20 which are formed around it, the parasitic NPN bipolar transistor (parasitic bipolar element 6) is formed whose collector, emitter and base are connected to the power source VDD, the Pad 1 and the ground GND, respectively.

With reference to FIG. 1, usually, as the discharging route of the ESD current between the Pad 1 and the power source VDD, there are a route 1: the Pad 1—the ESD protection circuit 2—the power source VDD, and a route 2: the Pad 1—the ESD protection circuit 3—the ESD protection circuit 5—the power source VDD. However, depending on a voltage applied between the power source VDD and the Pad 1 due to the ESD, there could be a route 3: the Pad 1—the parasitic bipolar element 6—the power source VDD, as the discharging route of the ESD current. For example, when a negative over-voltage with respect to the voltage of the power source VDD is applied to the Pad 1 due to electrostatic discharge, the voltage between the P-well 11 and the N-well 31 serves as forward bias, so that the parasitic bipolar element 6 operates based on base current flowing from the P-well 11 to the N-well 31. Also, in case of a circuit for applying the signal voltage of the power source VDD or more to the Pad 1, since the voltage is clamped by the ESD protection element, the ESD protection circuit cannot be arranged between the Pad 1 and the power source VDD, as shown in FIG. 2. Thus, the discharging route of the ESD current is limited to only the route 2. For this reason, the parasitic bipolar element 6 becomes easier to perform the discharging operation, so that a large amount of ESD current flows through the ESD protection circuit 3, to promote the element breakdown.

### [Layout of ESD Protection Element With Guard Rings]

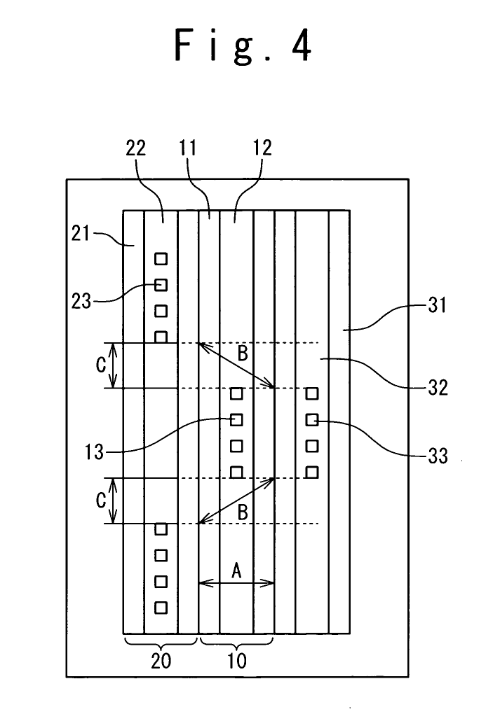

The layout of the ESD protection element 30 containing the guard rings according to the present invention will be described below with reference to FIGS. 3 and 4. In the present invention, the contacts 33 of the ESD protection element 30 for the substrate (N-well 31), the contacts 13 thereof for the P-type guard ring 10, and the contacts 23 thereof for the N-type guard ring 20 are suitably arranged, thereby suppressing the operation of the parasitic bipolar element 6.

With reference to FIG. 3, the ESD protection element 30 is formed in the rectangular N-well 31. An N⁺-type diffusion layer 32 is formed in the N-well 31 which surrounds the ESD protection element 30. The plurality of contacts 33 serving as emitter contacts in the parasitic bipolar element 6 are provided in a predetermined region in the N′-type diffusion layer 32, and they electrically connect the N-well 31 and the wiring connected to the Pad 1. A P-well 11 is formed to have a constant width and to surround the N-well 31. A P⁺-type diffusion layer 12 is formed to have a constant width narrower than the width of the P-well 11. The plurality of contacts 13 serving as base contacts in the parasitic bipolar element 6 are provided in a predetermined region on the P⁺-type diffusion layer 12, and they electrically connect the power source GND wiring and the P-well 11. An N-well 21 is formed to have a constant width and to surround the P-well 11. Also, the N⁺-type diffusion layer 22 is formed in the N-well 21 to have a constant width narrower than the width of the N-well 21. The plurality of contacts 23 serving as collector contacts in the parasitic bipolar element 6 are provided in a predetermined region on the N⁺-type diffusion layer 22, and they electrically connect the power source VDD wiring and the N-well 21.

The arrangement of the contacts 13, 23 and 33 will be described below in detail with reference to FIG. 4. The plurality of contacts 33 are provided in a predetermined interval along the side of the N-well 31 in the N⁺-type diffusion layer 32 in the periphery of the N-well 31. The plurality of contacts 13 are provided in a predetermined interval in the P⁺-type diffusion layer 12 formed in the P-well 11. The plurality of contacts 23 are provided in a predetermined interval in the N⁺-type diffusion layer 22 formed in the N-well 21. Here, the contacts 23 are not arranged in the region on the N⁺-type diffusion layer 22 opposite to the contacts 33 to put the P-well 11 therebetween, and they are provided in the region on the N⁺-type diffusion layer 22 which is separated by a predetermined distance. The contacts 13 are provided in the region on the P⁺-type diffusion layer 12 opposite to the contacts 33. It should be noted that the contacts 13, 23 and 33 may be provided on plural contacts basis. In FIG. 4, a contact group is composed of four contacts. As for the layout of the contact groups, similarly to the foregoing case, the contact group of the contacts 23 is not arranged in the region on the N⁺-type diffusion layer 22 opposite to the contact group of the contacts 33 to put the P-well 11 therebetween, with respect to the contact group of the contacts 33, but is arranged in the region on the N⁺-type diffusion layer 22 which is separated by a predetermined distance. It should be noted that the number of the contacts in the group is not limited to four. Any number of the contacts may be used if the effect of the guard ring is obtained.

The positional relation between the contacts 33 and the contacts 23 is set to ensure a distance B, which will be described later, so that the parasitic bipolar element 6 does not operate. The contact 23 arranged at the shortest distance from the contact 33 is arranged in the region, which is separated from the region opposite to the contact 33 by a distance C in the longitudinal direction of the N-well 21. At this time, when the width of the P-well 11 is assumed to be A, the distance B is preferred to be 1.2 times or more of the width A (however, B²=A²+C²).

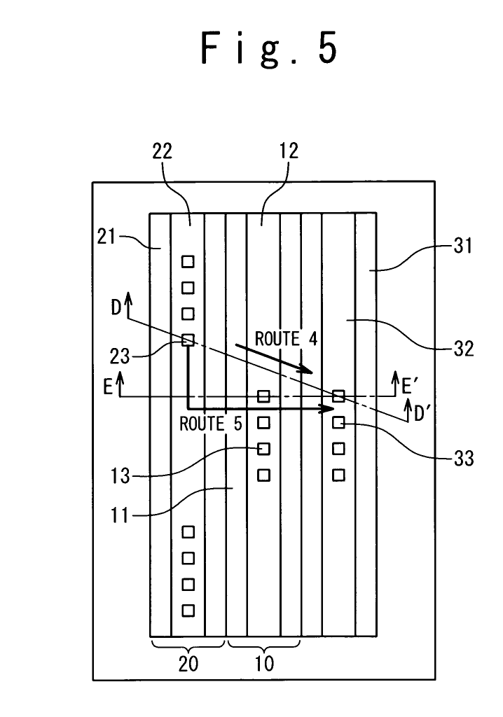

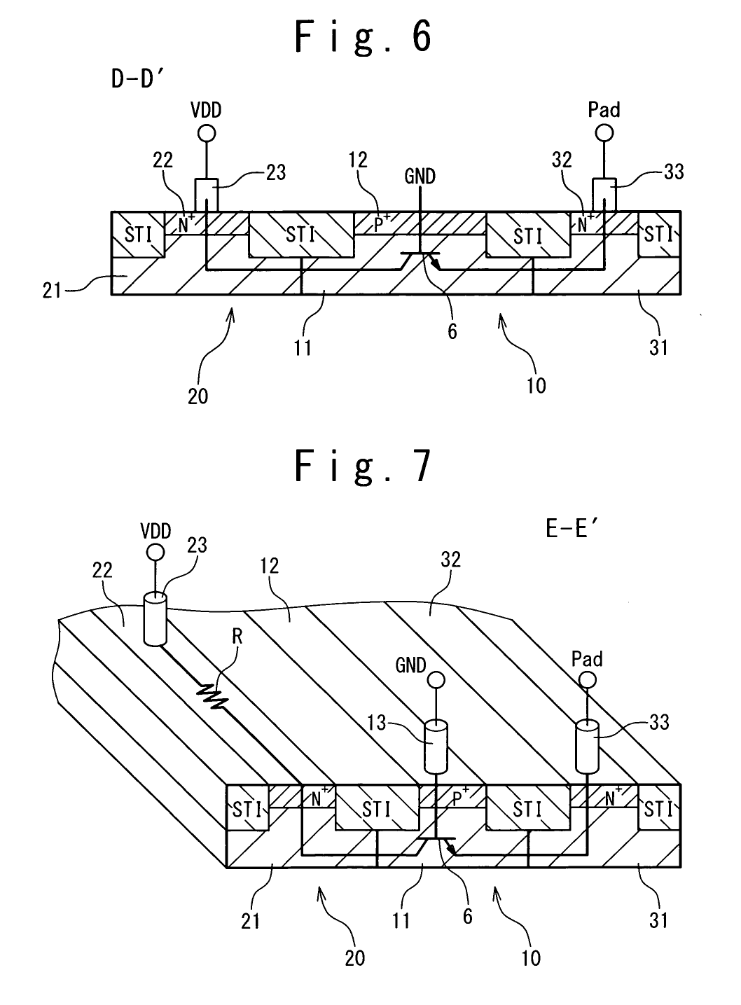

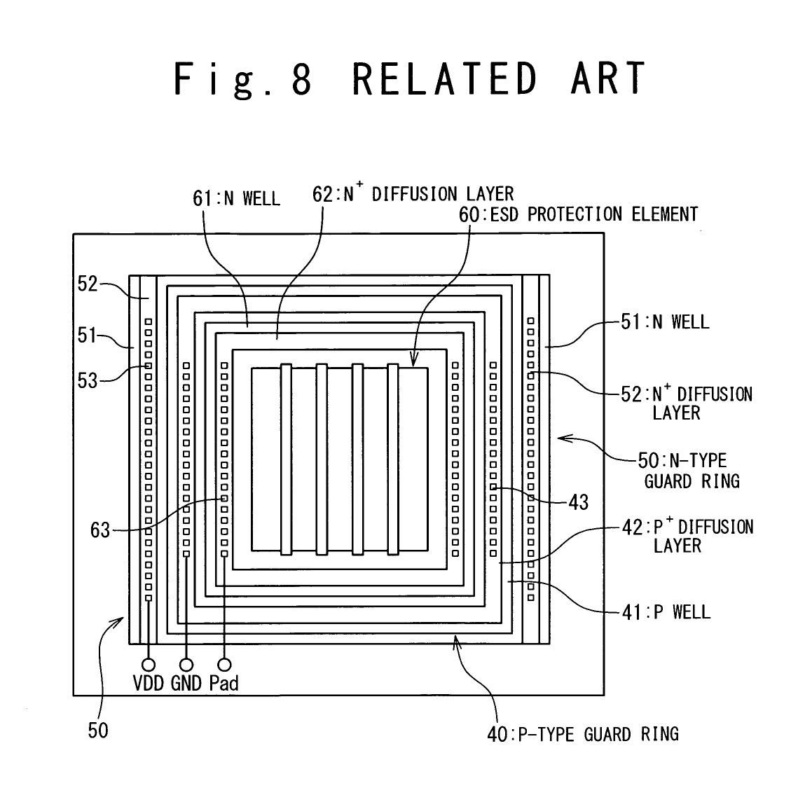

The shielding effect of the ESD current through the route 3 based on the arrangement of the contacts will be described below with reference to FIGS. 5 to 7. With reference to FIG. 5, the route when the ESD current flows through the parasitic bipolar element 6 will be described by using a route 4 and a route 5. FIG. 6 is a sectional view along the line D-D′ shown in FIG. 5. FIG. 7 is a perspective view showing the sectional structure along the line E-E′ shown in FIG. 5 and the positional relation between the contacts 13, 23 and 33 around it. It should be noted that in FIGS. 6 and 7, the N-wells 21 and 31 and the P-well 11 are formed in a P-type semiconductor substrate (not shown). With reference to FIG. 6, the region of the P-well 11 in the route 4 is wider than the width A of the P-type well 11 shown in FIG. 4. That is, the base region of the parasitic bipolar element 6 is extended, and the gain of the parasitic bipolar element 6 is decreased. For example, the width of the P-type well 11 is wider than that of the N-type well 21. For this reason, in order that the ESD current flows through the route 4, a larger base current is required, which results in the situation that the parasitic bipolar element 6 is hard to operate. Also, with reference to FIG. 7, in the route 5, the N⁺-type diffusion layer 22 to the contact 23 is longer than that of the conventional technique, and is equivalent to the configuration that a diffusion resistor R is connected to the collector of the parasitic bipolar element 6. For this reason, the ESD current is limited by this diffusion resistor R.

Moreover, as a method of limiting the ESD current flowing through the parasitic bipolar element 6, it is effective to increase the impurity concentration of the P-type guard ring 10 (the P-well 11 and the P⁺-type diffusion layer 12) serving as the base. For example, the impurity concentration of the P-type well 11 is higher than that of the N-type well 31.

On the other hand, since the contacts 13 and the contacts 33 are provided at the positions opposite to each other, the shortest distance is ensured. For this reason, since the absorption of the sufficient carriers can be performed, the breakdown caused by the ESD current can be prevented without any drop in the latch-up resistance.

As mentioned above, in the semiconductor device 100 according to the present invention, the contacts provided in the guard ring are arranged at the proper positions. Thus, the operation of the parasitic bipolar element 6 that is formed between the guard ring and the ESD protection circuit 3 can be suppressed, which can limit the ESD current flowing through the parasitic bipolar element 6. Thus, the element breakdown caused by the ESD current can be prevented. In particular, this is effective for the circuit in which the ESD protection element cannot be arranged between the Pad 1 and the power source VDD, as shown in FIG. 2. Also, the conventional technique is required to set the width of the guard ring wide so that the parasitic bipolar element does not operate. However, according to the present invention, since the contacts 23 are arranged to be separated from the contacts 33, the diffusion resistor R of the N⁺-type diffusion layer 22 on the current route is added, and the base width is further extended, which can control the operation of the parasitic bipolar element 6. Thus, the guard ring width is not required to be set wide, which can reduce the circuit area.

As mentioned above, the embodiments of the present invention have been detailed. However, the present invention is not limited to the specific configurations described in the above-mentioned embodiments. Even the change and modification in the range without departing from the spirit of the present invention are included in the present invention. The embodiments have been described with regard to the layout for suppressing the operation of the parasitic bipolar element 6 parasitized in the ESD protection circuit 3 that has the P-channel MOS transistor as the ESD element. However, the present invention can be applied to the ESD protection circuit 2 having the N-channel MOS transistor. Also, the ESD protection element may be the bipolar element.

Although the present invention has been described above in connection with several embodiments thereof, it would be apparent to those skilled in the art that those embodiments are provided solely for illustrating the present invention, and should not be relied upon to construe the appended claims in a limiting sense.

What is claimed is:

1. A semiconductor device comprising:
a first well of a first conductive type formed in a surface portion of a semiconductor substrate;
a first contact group connected with said first well;
a second well of a second conductive type formed to surround said first well in the surface portion of said semiconductor substrate;
a first guard ring provided on said second well;
a second contact group connected with said first guard ring;
a third well of the first conductive type formed to surround said second well in the surface portion of said semiconductor substrate;
a second guard ring provided on said third well; and
a third contact group connected with said second guard ring,
wherein said first to third wells form a transistor, and
a current flowing through said transistor is suppressed.

2. The semiconductor device according to claim 1, wherein said current is suppressed based on a relation of positions of said first to third contact groups.

3. The semiconductor device according to claim 2, wherein said third contact group is provided in a region of said second guard ring other than a region thereof opposite to said first contact group through said first guard ring.

4. The semiconductor device according to claim 2, wherein said second contact group is provided on a region of said first guard ring opposite to said first contact group through said first guard ring.

5. The semiconductor device according to claim 1, wherein said current is suppressed based on impurity concentrations of said first to third wells.

6. The semiconductor device according to claim 5, wherein the impurity concentration of said second well is higher than that of said first well.

7. The semiconductor device according to claim 1, wherein said current is suppressed based on widths of said first to third wells.

8. The semiconductor device according to claim 7, wherein the width of said second well is wider than that of said third well.

9. The semiconductor device according to claim 1, wherein an electrostatic discharge protection element is formed in said first well, and
said electrostatic discharge protection element has a plurality of MOS transistors connected in parallel.

10. A semiconductor device comprising:
a first well;
a pad connected with said first well;
a first guard ring provided around said first well; and
a second guard ring provided around said first guard ring,
wherein said pad is connected with a signal,
said first well is of a first conductive type and connected with said pad through first contacts provided on said first well,
said first guard ring comprises a second well of a second conductive type and second contacts provided on said second well to supply a first power source voltage to said second well,
said second guard ring comprises a third well of the first conductive type and third contacts provided on said third well to supply a second power source voltage to said third well, and
said third contacts are provided in a contact region of said second guard ring other than a region thereof which opposes to said first contacts through said first guard ring such that a current flowing through said first to third wells is suppressed.

11. The semiconductor device according to claim 10, wherein said second contact is provided in a contact region of said first guard ring which opposes to said first contact.

12. The semiconductor device according to claim 10, wherein each of said first to third contacts are formed as one of contacts of a corresponding one of first to third contact groups, and
said third contact group is provided in the contact region of said second guard ring other than opposes to said first contact group through said first guard ring but is provided in a fourth region of said second guard ring other than said third region.

13. The semiconductor device according to claim 10, wherein an electrostatic discharge protection element is formed in said first well.

14. The semiconductor device according to claim 13, wherein said electrostatic discharge protection element has a plurality of MOS transistors connected in parallel.

15. A semiconductor device comprising:
a pad for input or output of a signal;
a rectangular N-type well provided with an ESD protection element and electrically connected with said pad through a first contact group;
a P-type guard ring provided around said N-type well to have a predetermined width and connected with a low power source through a second contact group; and
an N-type guard ring provided around said P-type guard ring to have a predetermined width and connected with a high power source through a third contact group,
wherein said first contact group is provided in a predetermined interval along a side of said N-type well,
said second contact group is provided on said P-type guard ring in a predetermined interval,
said third contact group is provided on an N-type guard ring in a predetermined interval, and
said third contact group is not provided for a first region of said N-type guard ring opposing to said first contact group through said P-type guard ring and provided for a second region of said N-type guard ring other than said first region.

16. The semiconductor device according to claim 15, wherein said first contact group is provided on an N′-diffusion layer to surround said ESD protection element,
said P-type well has a predetermined width,
said second contact group is provided on a P⁺-type diffusion region of said P-type guard ring which is provided for said P-type well,
said N-type well has a predetermined width, and
said third contact group is provided on an N⁺-type diffusion region of said N-type guard ring which is provided for said N-type well.

17. The semiconductor device according to claim 15, wherein said second contact group is provided for a region opposing to said first contact group.

18. The semiconductor device according to claim 15, wherein said ESD protection element comprises a plurality of P channel MOS transistors connected in parallel to each other.

19. The semiconductor device according to claims 15, wherein when the width of said P-type guard ring is A, a distance between a region of said N-type guard ring opposing to said first contact group and said third contact group is C, and B²=A²+C², B is equal to or more than 1.2 times of A.
